(19) United States
(12) Patent Application Publication
(10) Pub. No.: US 2009/0163004 A1
(43) Pub. Date: Jun. 25, 2009

(54) Method of Fabricating Semiconductor Device

(76) Inventor: Yeong Sil Kim, Suwon-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/250,921

(22) Filed: Oct. 14, 2008

(30) Foreign Application Priority Data
Dec. 24, 2007 (KR) 10-2007-0136894

(51) Int. Cl. H01L 21/425

(52) U.S. Cl. 438/531; 257/E21.473

(57) ABSTRACT

Methods of fabricating a semiconductor device are provided. A photoresist pattern can be formed on an implantation target layer, and conductive impurities can be implanted into the implantation target layer using the photoresist pattern as a mask. A portion of the photoresist pattern can be removed, conductive impurities implanted in the photoresist pattern can be cleaned, and the remaining portion of the photoresist pattern can be removed.

### CROSS-REFERENCE TO RELATED APPLICATION

The present application claims the benefit under 35 U.S.C. §119 of Korean Patent Application No. 10-2007-0136894, filed Dec. 24, 2007, which is hereby incorporated by reference in its entirety.

### BACKGROUND

During the process of fabricating a semiconductor device, conductive impurities are typically implanted many times. In general, a photoresist pattern is used as an implantation mask during the implantation process. While removing the photoresist pattern, impurities are often generated which can negatively impact the performance of the semiconductor device.

Thus, there exists a need in the art for an improved method for removing a photoresist pattern during a process of fabricating a semiconductor device.

### BRIEF SUMMARY

Embodiments of the present invention provide methods of fabricating a semiconductor device, in which impurities that may be generated while removing a mask pattern can be reduced.

According to an embodiment, a method of fabricating a semiconductor device can comprise: forming a photoresist pattern on an implantation target layer disposed on a semiconductor substrate; implanting conductive impurities into the implantation target layer using the photoresist pattern as a mask, wherein a portion of the conductive impurities are implanted into the photoresist pattern; removing a portion of the photoresist pattern; cleaning the conductive impurities implanted in the photoresist pattern using an acid solution; and removing the remaining photoresist pattern.

According to another embodiment, a method of fabricating a semiconductor device can comprise: forming a photoresist film on a semiconductor substrate; implanting conductive impurities into the semiconductor substrate to form an impurity layer in the photoresist film; primarily removing a portion of the photoresist film at a temperature below a boiling point of the photoresist film; cleaning the conductive impurities of the impurity layer; and removing the photoresist film.

According to still another embodiment, a method of fabricating a semiconductor device can comprise: forming a first photoresist layer on a semiconductor substrate, an impurity layer on the first photoresist layer, and a second photoresist layer on the impurity layer; removing the second photoresist layer at a temperature below a boiling point of the first photoresist layer; cleaning the conductive impurities of the impurity layer; and removing the first photoresist layer.

The methods of fabricating a semiconductor device according to embodiments of the present invention can include a process of removing a photoresist pattern in steps, and a process of cleaning the conductive impurities implanted into the photoresist pattern between steps of removing the photoresist pattern.

Furthermore, the methods of fabricating a semiconductor device according to embodiments can inhibit material contained in the impurity layer from being spattered, since removing processes (such as an ashing process) can be performed at a temperature below the boiling point of the photoresist material.

Thus, embodiment of the present invention can reduce the amount of by-products that may be generated during the process of removing the photoresist film or photoresist pattern.

### BRIEF DESCRIPTION OF THE DRAWINGS

FIGS. 1 through 5 are cross-sectional views illustrating a process of removing a photoresist pattern according to an embodiment of the present invention.

### DETAILED DESCRIPTION

When the terms “on” or “over” or “above” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

Reference will now be made in detail to the embodiments of the present disclosure, examples of which are illustrated in the accompanying drawings.

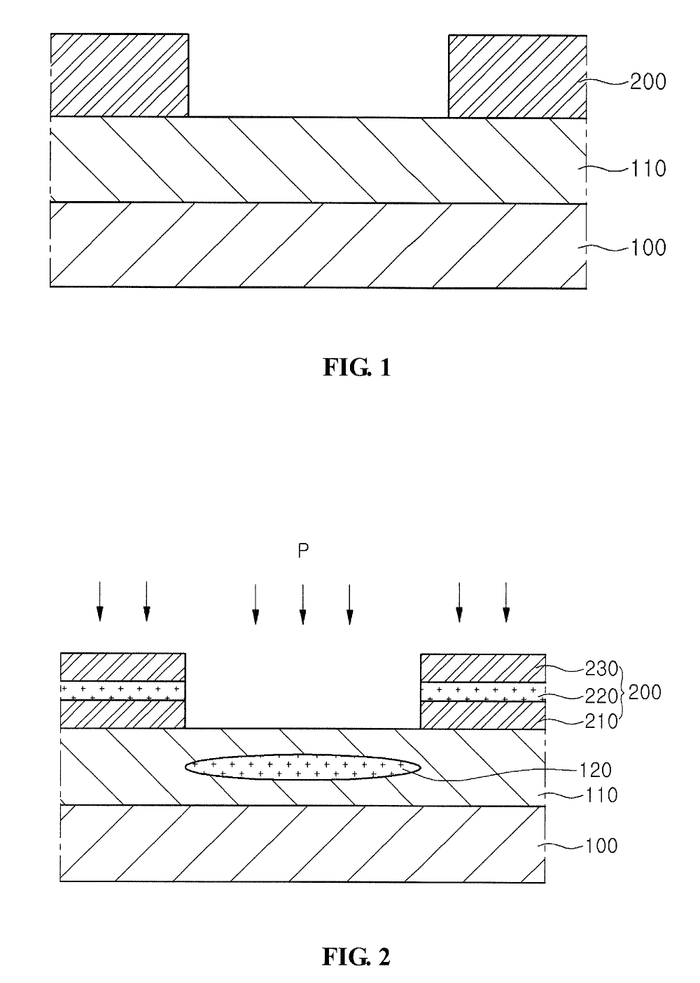

FIGS. 1 through 5 are cross-sectional views illustrating a process of removing a photoresist pattern according to an embodiment of the subject invention.

Referring to FIG. 1, an implantation target layer 110 can be formed on a silicon substrate 100. The implantation target layer 110 can be for implanting conductive impurities. The implantation target layer 110 can be any suitable material known in the art, for example, a silicon wafer, an epitaxial layer, or a p-type well. Although the implantation target layer 110 is illustrated as a separate layer on a substrate 100, in one embodiment, the implantation target layer 110 can be part of the substrate 100.

After that, a photoresist film can be formed on the implantation target layer 110. The photoresist film can then be patterned to form a photoresist pattern 200 on the implantation target layer 110. The photoresist film can be patterned by, for example, an exposure process and a development process.

Referring to FIG. 2, conductive impurities can be selectively implanted into the implantation target layer 110 using the photoresist pattern 200 as a mask. Although phosphorus (P) is shown in FIG. 2 as conductive impurities, embodiments of the present invention are not limited thereto. The conductive impurities can be any suitable conductive impurities known in the art.

At this time, the conductive impurities can be implanted into the implantation target layer 110 to a predetermined depth, thereby forming a conductive region 120 in the implantation target layer 110. During the implantation process, some conductive impurities can be implanted into the photoresist pattern 200, thereby forming an impurity layer 220 in the photoresist pattern 200.

Any suitable amount of conductive impurities can be implanted into the implantation target layer 110. In one embodiment, conductive impurities ranging from about 5×10¹⁴ atoms/cm² to about 5×10¹⁶ atoms/cm² can be implanted into the implantation target layer 110.

In certain embodiments, the impurity layer 220 can be formed in the photoresist pattern 200, including conductive impurities at a high concentration.

The photoresist pattern 200 can be divided into the impurity layer 220, a lower photoresist pattern 210 disposed under the impurity layer 220, and an upper photoresist pattern 230 disposed on the impurity layer 220.

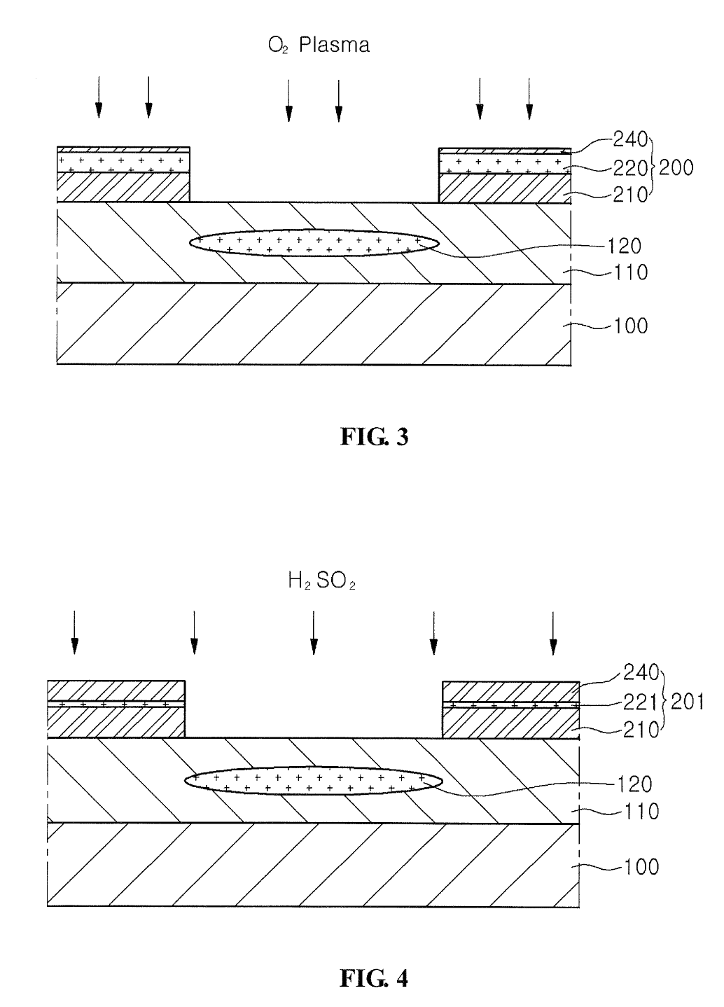

Referring to FIG. 3, a portion of the upper photoresist pattern 230 disposed on the impurity layer 220 can be primarily removed using plasma. The plasma can be, for example, oxygen (O₂) plasma. In an embodiment, the portion of the upper photoresist pattern 230 disposed on the impurity layer 220 can be primarily removed by an ashing process using plasma.

In an embodiment, a portion of the other upper photoresist pattern 230 can be left on the impurity layer as a residual photoresist pattern 240. Thus, reaction of the conductive impurities contained in the impurity layer 220 to oxygen can be inhibited, thereby reducing the amount of by-products generated by reaction of the impurity layer 220 with oxygen.

For example, in embodiments in which the conductive impurities include P, a small amount of phosphorus oxide (PₓO_{y}, where x and y are positive integers) can be generated. However, since the residual photoresist pattern 240 is present, the amount of such impurities can be reduced.

In certain embodiments, the primary removing process can be performed at a temperature below the boiling point of the photoresist pattern 200.

The photoresist pattern 200 can be any suitable material known in the art, for example, a photosensitive substance, resin, solvent resolving the resin, or any combination thereof. In an embodiment, the primary removing process can be carried out at a temperature below the boiling point of the solvent included in the photoresist pattern 200.

In a particular embodiment, the primary removing process can be carried out at a temperature between the melting point of the photoresist pattern 200 and the boiling point of the photoresist pattern 200.

For example, in one embodiment, the primary removing process can be performed at a temperature of about 155° C. or less. In a further embodiment, the primary removing process can be performed at a temperature of from about 140° C. to about 150° C.

Since the primary removing process can be carried out at a temperature below the boiling point of the photoresist pattern 200, the lower photoresist pattern 210 disposed under the impurity layer 220 can be inhibited from evaporating, thereby inhibiting cracking or spattering of the impurity layer 220 and the upper photoresist pattern 230 disposed on the impurity layer 220.

That is, since the primary removing process can be carried out at a temperature below the boiling point of the photoresist pattern 200, the impurity layer 220 and the upper photoresist pattern 230 disposed on the impurity layer 220 can be inhibited from cracking. Thus, by-products that are generated by reaction of oxygen with the conductive impurities contained in the impurity layer 220 can be reduced.

Referring to FIG. 4, after the primary removing process, the conductive impurities contained in the impurity layer 220 can be cleaned by an acid solution. The acid solution can be, for example, a sulfuric acid (H₂SO₄)

In an embodiment, the cleaning process can thin the impurity layer 220 to form a thin impurity layer 221. This can cause the residual photoresist pattern 240 disposed on the thin impurity layer 221 to become thicker.

That is, the conductive impurities contained in the impurity layer 220 can be effectively removed, thereby reducing the thickness of the impurity layer 220 and increasing the thickness of the residual photoresist pattern 240.

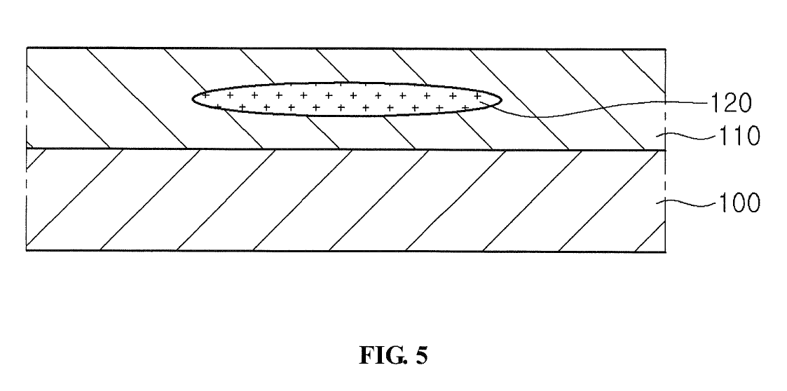

Referring to FIG. 5, the remaining photoresist pattern 201 can be removed by plasma. The plasma can be, for example, oxygen plasma. Since the conductive impurities contained in the photoresist pattern 200 have been mostly removed by the acid solution, the generation of by-products through the reaction of oxygen and the conductive impurities can be inhibited.

Thus, methods of removing the photoresist pattern 200 according to embodiments of the present invention provide reduced amounts of by-products generated by the reaction of oxygen and conductive impurities.

Furthermore, the number of defective semiconductor devices caused by the by-products can be reduced using the methods of the present invention. Therefore, yield can be increased.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of fabricating a semiconductor device, comprising:
forming a photoresist pattern on an implantation target layer;
implanting conductive impurities into the implantation target layer using the photoresist pattern as a mask, wherein a portion of the conductive impurities are implanted into the photoresist pattern;
removing a portion of the photoresist pattern using plasma;
cleaning the conductive impurities implanted in the photoresist pattern using an acid solution; and
removing the remaining photoresist pattern.

2. The method according to claim 1, wherein the forming the photoresist pattern comprises:
forming a photoresist film on the implantation target layer; and
selectively removing a portion of the photoresist film to form the photoresist pattern.

3. The method according to claim 1, wherein implanting conductive impurities into the implantation target layer comprises implanting conductive impurities in an amount of from about 5×10¹⁴ atoms/cm² to about 5×10¹⁶ atoms/cm².

4. The method according to claim 1, wherein removing the portion of the photoresist pattern is performed at a temperature that is less than a boiling point of the photoresist pattern.

5. The method according to claim 4, wherein removing the portion of the photoresist pattern is performed at a temperature of about 155° C. or less.

6. The method according to claim 4, wherein removing the portion of the photoresist pattern is performed at a temperature of from about 140° C. to about 150° C.

7. The method according to claim 1, wherein the plasma is oxygen plasma.

8. The method according to claim 1, wherein the acid solution is a sulfuric acid solution.

9. The method according to claim 1, wherein the photoresist pattern comprises a photosensitive substance, resin, and a solvent for resolving the resin.

10. The method according to claim 9, wherein removing the portion of the photoresist pattern is performed at a temperature that is less than a boiling point of the solvent for resolving the resin.

11. A method of fabricating a semiconductor device, comprising:
forming a photoresist film on a semiconductor substrate;
implanting conductive impurities into the semiconductor substrate, forming an impurity layer in the photoresist film;
primarily removing a portion of the photoresist film at a temperature below a boiling point of the photoresist film;
cleaning the conductive impurities of the impurity layer; and
removing the remaining photoresist film.

12. The method according to claim 11, wherein cleaning the conductive impurities of the impurity layer comprises using an acid solution.

13. The method according to claim 12, wherein the acid is sulfuric acid.

14. The method according to claim 11, wherein primarily removing a portion of the photoresist film comprises using plasma.

15. The method according to claim 14, wherein the plasma is oxygen plasma.

16. A method of fabricating a semiconductor device, comprising:
forming a first photoresist layer on a semiconductor substrate, an impurity layer on the first photoresist layer, and a second photoresist layer on the impurity layer;
removing at least a portion of the second photoresist layer at a temperature below a boiling point of the first photoresist layer;
cleaning the conductive impurities of the impurity layer; and
removing the first photoresist layer.

17. The method according to claim 16, wherein forming the first photoresist layer on the semiconductor substrate, the impurity layer on the first photoresist layer, and the second photoresist layer on the impurity layer comprises:
forming a photoresist pattern on the semiconductor substrate; and
implanting conductive impurities into the photoresist pattern, thereby forming the impurity layer on the first photoresist layer and under the second photoresist layer.

18. The method according to claim 16, wherein removing the second photoresist layer comprises performing an ashing process using plasma.

19. The method according to claim 18, wherein the plasma is oxygen plasma.

20. The method according to claim 16, wherein cleaning the conductive impurities of the impurity layer comprises using an acid solution.
